(19) United States
(12) Patent Application Publication
(10) Pub. No.: US 2020/0035712 A1
(43) Pub. Date: Jan. 30, 2020

(54) THIN FILM TRANSISTOR ARRAY SUBSTRATE, MANUFACTURING METHOD THEREOF AND FLEXIBLE LIQUID CRYSTAL DISPLAY PANEL

(71) Applicant: Wuhan China Star Optoelectronics Technology Co., Ltd., Wuhan (CN)

(72) Inventor: Bingkun Yin, Wuhan (CN)

(73) Assignee: Wuhan China Star Optoelectronics Technology Co., Ltd., Wuhan (CN)

(21) Appl. No.: 16/313,048

(22) PCT Filed: Sep. 22, 2018
(86) PCT No.: PCT/CN2018/107154

§ 371 Date: Dec. 23, 2018

(30) Foreign Application Priority Data
Jul. 24, 2018 (CN) 201810822302.5

(51) Int. Cl. H01L 27/12; G02F 1/1368; G02F 1/1333

(52) U.S. Cl. CPC H01L 27/1218; G02F 1/133305; G02F 1/1368; H01L 27/1262

(57) ABSTRACT

Provided are a thin film transistor array substrate, a manufacturing method thereof and a flexible liquid crystal display panel. The TFT array substrate includes a flexible substrate, a first metal layer disposed over the flexible substrate, an insulating layer covering the first metal layer and a second metal layer disposed on the insulating layer. The first metal layer includes a plurality of connection portions at intervals. The second metal layer includes a plurality of bonding terminals at intervals. Each bonding terminal corresponds to one connecting portion. The insulating layer is provided with a plurality of via holes respectively on the connecting portions. The plurality of bonding terminals are respectively in contact with the corresponding connecting portions through the via holes on the corresponding connecting portions.

### FIELD OF THE INVENTION

The present invention relates to a display field, and more particularly to a thin film transistor array substrate, a manufacturing method thereof and a flexible liquid crystal display panel.

### BACKGROUND OF THE INVENTION

In the display skill field, the Liquid Crystal Display (LCD) and other panel displays have been gradually replaced the Cathode Ray Tube (CRT) displays. A liquid crystal display possesses advantages of being ultra thin, power saved and radiation free and has been widely utilized.

Most of the liquid crystal displays on the present market are back light type liquid crystal display devices, which comprise a liquid crystal display panel and a back light module. Generally, the liquid crystal display panel comprises a Color Filter (CF) substrate, a Thin Film Transistor (TFT) substrate, Liquid Crystal (LC) sandwiched between the CF substrate and the TFT substrate and sealant. The working principle of the liquid crystal display panel is to locate liquid crystal molecules between two parallel glass substrates, and a plurality of vertical and horizontal tiny electrical wires are between the two glass substrates. The light of back light module is reflected to generate images by applying driving voltages to control whether the liquid crystal molecules to be changed directions.

In the existing TFT array substrate, a first metal layer including a gate line and a TFT element is formed on the substrate, and in order for bonding the first metal layer and the chip (IC) outside the TFT array substrate. Generally, a bonding pad in the first metal layer is disposed in the bonding area at the edge of the TFT array substrate, and the pin of the chip is connected to the bonding terminal to realize the bonding of the chip and the first metal layer.

The flexible liquid crystal display panel possesses the characteristics of ultra-thin, light weight, flexible winding and high degree design possibility and possesses a broad market in wearable, mobile communication, television, commercial advertising and military applications. The substrate of the TFT array substrate applied to the flexible liquid crystal display panel is usually made of a flexible material, such as polyethylene terephthalate (PET) or polyimide (PI). The coefficient of thermal expansion is large, and the substrate is extremely prone to thermal expansion in a high temperature environment. When the bonding terminal of the first metal layer is formed on the substrate, and the substrate thermally expands, the bonding terminal will also thermally expand accordingly. Therefore, a bonding offset occurs between the bonding terminal and the pin of the chip, which affects the bonding of the first metal layer and the chip. In severe cases, the chip bonding will be poor, which affects the normal display of the display panel.

### SUMMARY OF THE INVENTION

An objective of the present invention is to provide a thin film transistor (TFT) array substrate, which can eliminate the bonding offset problem of the TFT array substrate and the chip, and can improve the chip bonding yield of the flexible liquid crystal display panel.

Another objective of the present invention is to provide a manufacturing method of a thin film transistor (TFT) array substrate, which can eliminate the bonding offset problem of the TFT array substrate and the chip, and can improve the chip bonding yield of the flexible liquid crystal display panel.

Another objective of the present invention is to provide a flexible display panel, which can eliminate the bonding offset problem of the TFT array substrate and the chip, and can improve the chip bonding yield of the flexible liquid crystal display panel.

For realizing the aforesaid objectives, the present invention first provides a thin film transistor (TFT) array substrate, comprising: a flexible substrate, a first metal layer disposed over the flexible substrate, an insulating layer covering the first metal layer and a second metal layer disposed on the insulating layer;

wherein the first metal layer comprises a plurality of connection portions at intervals; the second metal layer comprises a plurality of bonding terminals at intervals; each bonding terminal corresponds to one connecting portion; the insulating layer is provided with a plurality of via holes respectively on the connecting portions; the plurality of bonding terminals are respectively in contact with the corresponding connecting portions through the via holes on the corresponding connecting portions.

A material of the flexible substrate is Polyethylene terephthalate (PET) or Polyimide (PI).

Each of the bonding terminals comprises an end portion and a trace, and for each of the bonding terminals, a projection of the end portion in a vertical direction is located at a side of the corresponding connecting portion away from a center of the flexible substrate, and one end of the trace is connected to the end portion, and an other end of the trace is in contact with the corresponding connecting portion through a via hole on the corresponding connecting portion.

Shapes of the plurality of connecting portions are all rectangular; shapes of the plurality of end portions are all rectangular.

The plurality of connecting portions are arranged in a straight line, and the plurality of end portions are arranged in a straight line.

An arrangement direction of the plurality of connecting portions is parallel to an arrangement direction of the plurality of end portions.

The insulating layer is correspondingly provided with two via holes on each of connecting portions, and the plurality of bonding terminals are respectively in contact with the corresponding connecting portions through the two via holes on the corresponding connecting portions.

The TFT array substrate further comprises a buffer layer disposed on the flexible substrate;

wherein the first metal layer is disposed on the buffer layer.

The present invention further provides a manufacturing method of a thin film transistor (TFT) array substrate, comprising steps of:

Step S1, providing a flexible substrate;

Step S2, forming a buffer layer on the flexible substrate;

Step S3, depositing a metal material on the buffer layer, and patterning the metal material to form a first metal layer; wherein the first metal layer comprises a plurality of connecting portions at intervals;

Step S4, forming an insulating layer covering the first metal layer, and patterning the insulating layer to form a plurality of via holes respectively disposed on the plurality of connecting portions;

Step S5, depositing a metal material on the insulating layer, and patterning the metal material to form a second metal layer; wherein the second metal layer comprises a plurality of bonding terminals at intervals; each bonding terminal corresponds to one connecting portion; the plurality of bonding terminals are respectively in contact with the corresponding connecting portions through the via holes on the corresponding connecting portions.

The present invention further provides a flexible liquid crystal display panel including the aforesaid TFT array substrate.

The benefits of the present invention are: the TFT array substrate includes a flexible substrate, a first metal layer disposed over the flexible substrate, an insulating layer covering the first metal layer and a second metal layer disposed on the insulating layer. The first metal layer includes a plurality of connection portions at intervals. The second metal layer includes a plurality of bonding terminals at intervals. Each bonding terminal corresponds to one connecting portion. The insulating layer is provided with a plurality of via holes respectively on the connecting portions. The plurality of bonding terminals are respectively in contact with the corresponding connecting portions through the via holes on the corresponding connecting portions. After the bonding terminal is connected to the pin of a chip to bond the TFT array substrate and the chip, an expansion of the first metal layer caused by thermal expansion of the flexible substrate does not cause bonding offset of the chip and the TFT array substrate, thereby improving a chip bonding yield of the flexible liquid crystal display panel. The manufacturing method of the TFT array substrate of the present invention can eliminate the bonding offset problem of the TFT array substrate and the chip, and can improve the chip bonding yield of the flexible liquid crystal display panel. The flexible display panel of the present invention can eliminate the bonding offset problem of the TFT array substrate and the chip, and can improve the chip bonding yield of the flexible liquid crystal display panel.

### BRIEF DESCRIPTION OF THE DRAWINGS

In order to better understand the characteristics and technical aspect of the invention, please refer to the following detailed description and accompanying drawings of the present invention. However, the drawings are provided for reference only and are not intended to be limiting of the invention.

In drawings,

FIG. 1 is a cross-sectional view diagram of a thin film transistor (TFT) array substrate of the present invention;

FIG. 2 is a top view diagram of a TFT array substrate of the present invention;

FIG. 3 is a diagram of relative positions of a first metal layer and a second metal layer of the TFT array substrate of the present invention;

FIG. 4 is a flowchart of a manufacturing method of the TFT array substrate of the present invention;

FIG. 5 is a diagram of Step S1 and Step S2 of the manufacturing method of the TFT array substrate of the present invention;

FIG. 6 and FIG. 7 are diagrams of Step S3 of the manufacturing method of the TFT array substrate of the present invention;

FIG. 8 and FIG. 9 are diagrams of Step S4 of the manufacturing method of the TFT array substrate of the present invention.

### DETAILED DESCRIPTION OF PREFERRED EMBODIMENTS

For better explaining the technical solution and the effect of the present invention, the present invention will be further described in detail with the accompanying drawings and the specific embodiments.

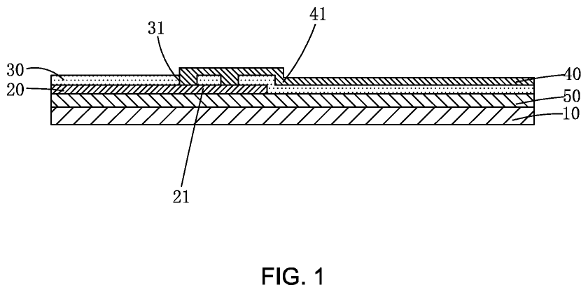

Please refer to FIGS. 1 to 3. The thin film transistor (TFT) array substrate comprises a flexible substrate 10, a first metal layer 20 disposed over the flexible substrate 10, an insulating layer 30 covering the first metal layer 20 and a second metal layer 40 disposed on the insulating layer 30.

The first metal layer 20 comprises a plurality of connection portions 21 at intervals. The second metal layer 40 comprises a plurality of bonding terminals 41 at intervals. Each bonding terminal 41 corresponds to one connecting portion 21. The insulating layer 30 is provided with a plurality of via holes 31 respectively on the connecting portions 31. The plurality of bonding terminals 41 are respectively in contact with the corresponding connecting portions 21 through the via holes 31 on the corresponding connecting portions 21.

Specifically, a material of the flexible substrate 10 may be a flexible material commonly used in the prior art for fabricating a substrate, such as PET or PI.

Specifically, the flexible substrate 10 includes a display area and a bonding area located outside the display area, and the connecting portions 21 and the bonding terminals 41 are respectively disposed corresponding to the bonding area.

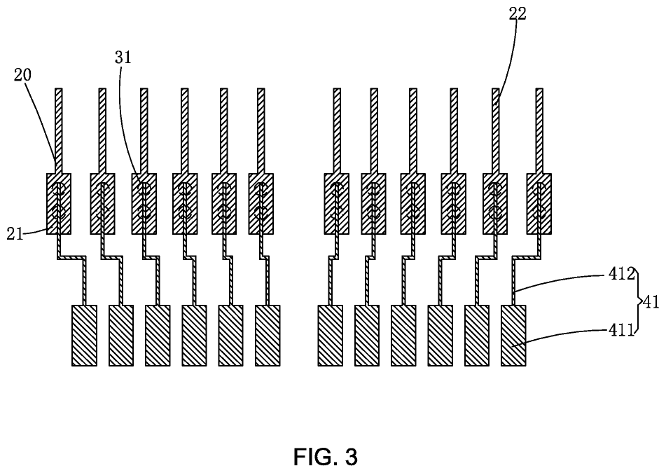

Specifically, referring to FIG. 3, the first metal layer 20 further includes a plurality of gate lines 22 respectively connected to the plurality of connecting portions 21, and the plurality of gate lines 22 are disposed corresponding to the display area.

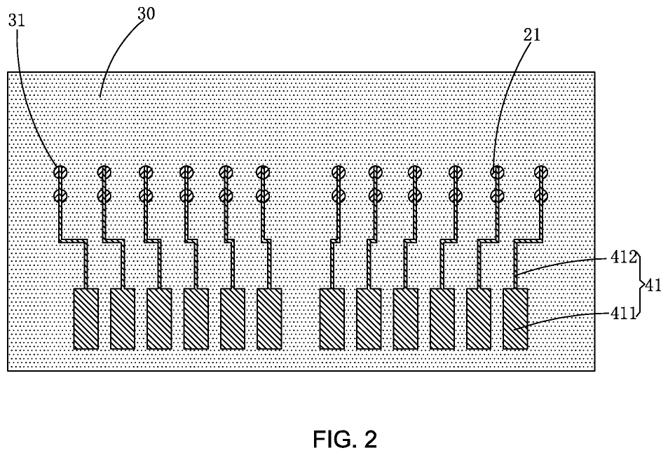

Specifically, referring to FIGS. 2 and 3, each of the bonding terminals 41 comprises an end portion 411 and a trace 412, and for each of the bonding terminals 41, a projection of the end portion 411 in a vertical direction is located at a side of the corresponding connecting portion 21 away from a center of the flexible substrate 10, and one end of the trace 412 is connected to the end portion 411, and an other end of the trace is in contact with the corresponding connecting portion 21 through a via hole 31 on the corresponding connecting portion 21.

Specifically, in the embodiment shown in FIGS. 2 and 3, shapes of the plurality of connecting portions 21 are all rectangular. Shapes of the plurality of end portions 411 are all rectangular. Certainly, the plurality of connecting portions 21 and the plurality of end portions 411 may have other shapes according to actual product requirements.

Specifically, in the embodiment shown in FIGS. 2 and 3, the plurality of connecting portions 21 are arranged in a straight line, and the plurality of end portions 411 are arranged in a straight line. Furthermore, an arrangement direction of the plurality of connecting portions 21 is parallel to an arrangement direction of the plurality of end portions 411.

Preferably, the insulating layer 30 is correspondingly provided with two via holes 31 on each of connecting portions 21, and the plurality of bonding terminals 41 are respectively in contact with the corresponding connecting portions 21 through the two via holes 31 on the corresponding connecting portions 21, thus to enhance the connection of each of bonding terminals 41 and the corresponding connecting portions 21.

Specifically, referring to FIG. 1, the TFT array substrate further comprises a buffer layer 50 disposed on the flexible substrate 50. The first metal layer 20 is disposed on the buffer layer 50.

Specifically, the TFT array substrate further includes an active layer and a source drain electrode layer disposed above the first metal layer 20 and insulated from the first metal layer 20, and a transparent conductive electrode layer disposed above the source drain electrode layer and insulated from the source drain electrode layer. The second metal layer 40 may be disposed on an insulating structure layer between the transparent conductive electrode layer and the source drain electrode layer, and the insulating layer 30 is formed by laminating an insulating structure layer between the first metal layer 20 and the active layer, the source drain electrode layer and the insulating structure layer between the source drain electrode layer and the transparent conductive electrode layer.

Specifically, in the TFT array substrate of the present invention, the plurality of via holes 31 are respectively located on the plurality of connection portions 21 of the first metal layer 20 in the insulating layer 30 on the first metal layer 20, and then, the second metal layer 40 is formed on the insulating layer 30, such that the plurality of bonding terminals 41 of the second metal layer 40 are respectively in contact with the plurality of connecting portions 21 through the via holes 31, thereby the plurality of bonding terminals 41 are electrically connected to the first metal layer 40. Thus, the TFT array substrate is bonded to the chip by using the plurality of bonding terminals 41 to bond the chip and the first metal layer 20, an expansion of the first metal layer 20 caused by thermal expansion of the flexible substrate 10 still will not cause bonding offset of the pin of the chip and the bonding terminals 41, that is, bonding offset of the chip and the TFT array substrate will not occur, thereby improving a chip bonding yield of the flexible liquid crystal display panel.

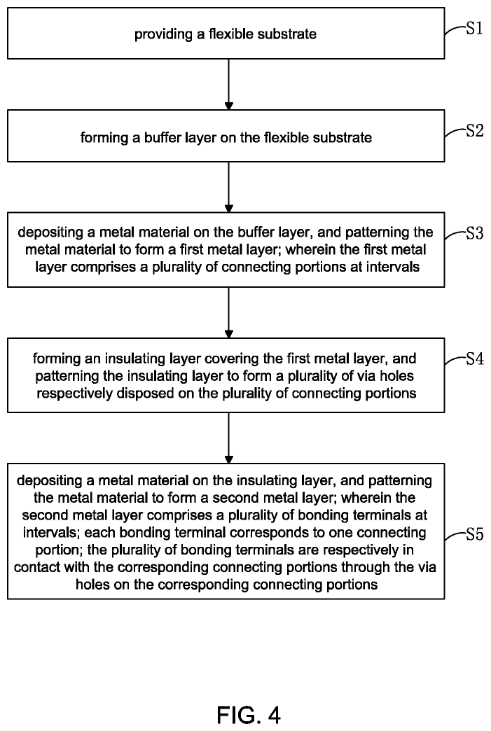

Please refer to FIG. 4. On the basis of the same inventive idea, the present invention further provides a manufacturing method of a thin film transistor (TFT) array substrate, comprising steps of:

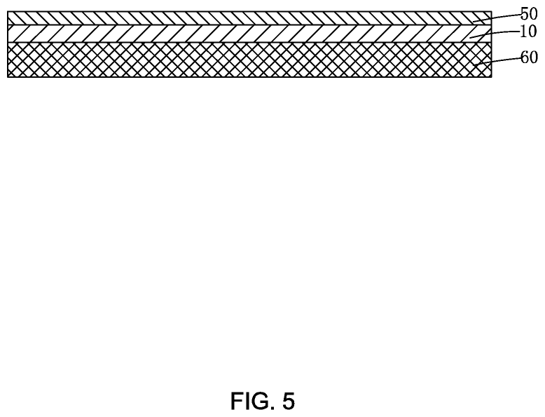

Step S1, as shown in FIG. 5, providing a flexible substrate 10.

Specifically, referring to FIG. 5, the flexible substrate 10 provided in Step S1 is formed on a rigid substrate 60.

Specifically, a material of the flexible substrate 10 may be a flexible material commonly used in the prior art for fabricating a substrate, such as PET or PI.

Specifically, a material of the rigid substrate 60 may be glass.

Specifically, the flexible substrate 10 includes a display area and a bonding area located outside the display area.

Step S2, as shown in FIG. 5, forming a buffer layer 50 on the flexible substrate 10.

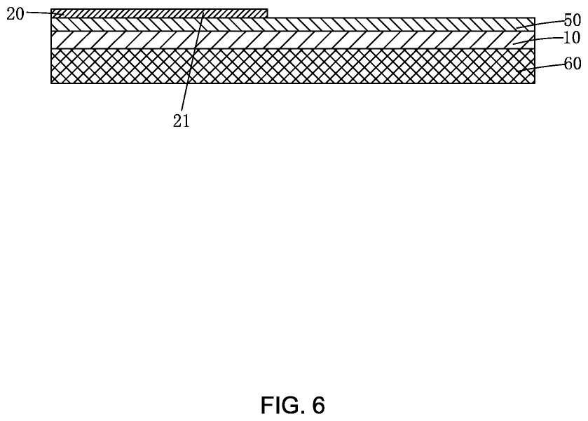

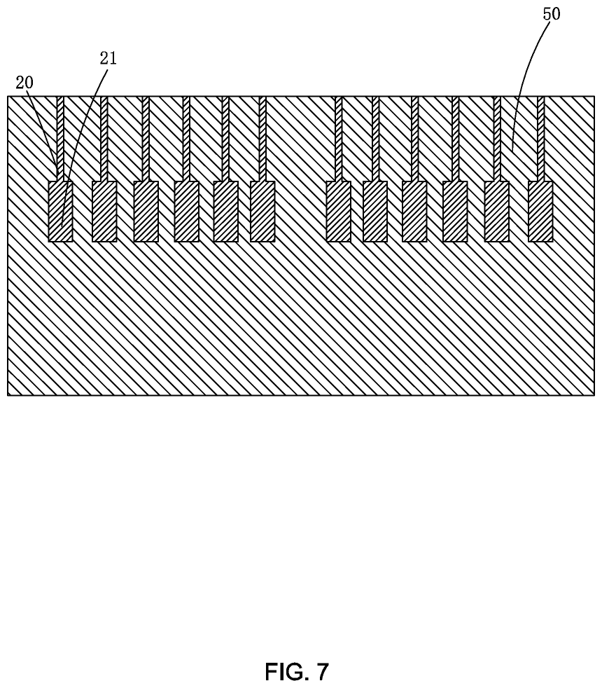

Step S3, as shown in FIG. 6 and FIG. 7, depositing a metal material on the buffer layer 50, and patterning the metal material to form a first metal layer 20. The first metal layer 20 comprises a plurality of connection portions 21 at intervals.

Specifically, the connecting portions 21 are disposed corresponding to the bonding area.

Specifically, in the embodiment shown in FIG. 7, shapes of the plurality of connecting portions 21 are all rectangular. Certainly, the plurality of connecting portions 21 may have other shapes according to actual product requirements.

Specifically, in the embodiment shown in FIG. 7, the plurality of connecting portions 21 are arranged in a straight line.

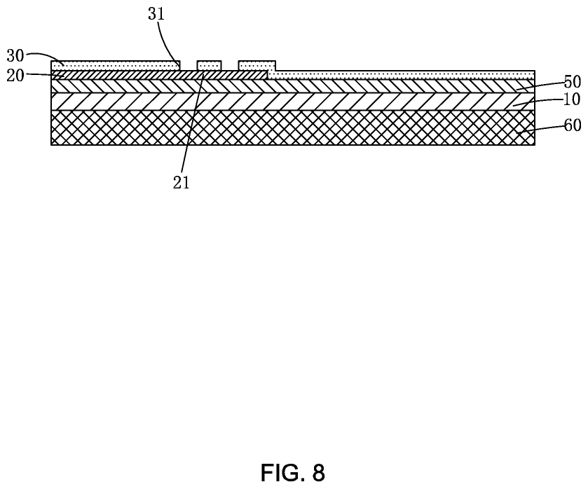

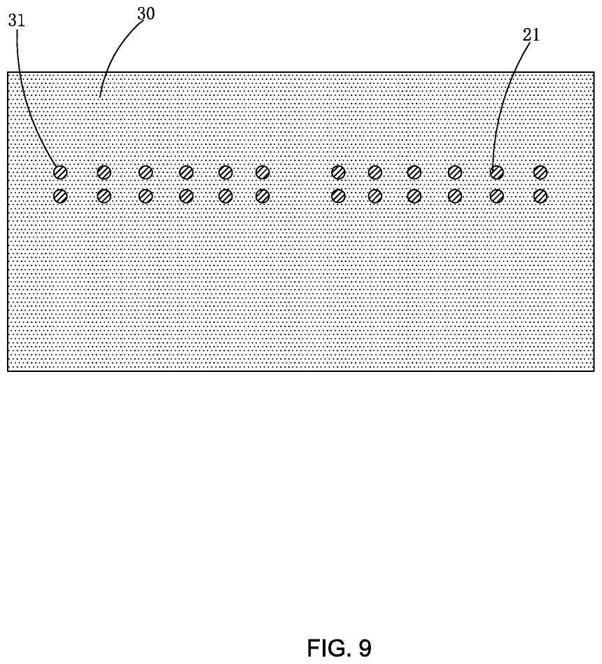

Step S4, as shown in FIG. 8 and FIG. 9, forming an insulating layer 30 covering the first metal layer 20, and patterning the insulating layer 30 to form a plurality of via holes 31 respectively disposed on the plurality of connecting portions 21.

Preferably, the insulating layer 30 is correspondingly provided with two via holes 31 on each of connecting portions 21, thus to enhance the connection of each of bonding terminals 41 and the corresponding connecting portions 21.

Specifically, the process of forming the insulating layer 30 in Step S4 specifically is that, an active layer and a source drain electrode layer insulated from the first metal layer 20 are formed over the first metal layer 20. Then, a transparent conductive electrode layer insulated from the source drain electrode layer is formed over the source drain electrode layer. An insulating structure layer between the first metal layer 20 and the active layer, the source drain electrode layer and an insulating structure layer between the source drain electrode layer and the transparent conductive electrode layer are laminated to form the insulating layer 30.

Step S5, as shown in FIGS. 1 to 3, depositing a metal material on the insulating layer 30, and patterning the metal material to form a second metal layer 40. The second metal layer 40 comprises a plurality of bonding terminals 41 at intervals. Each bonding terminal 41 corresponds to one connecting portion 21. The plurality of bonding terminals 41 are respectively in contact with the corresponding connecting portions 21 through the via holes 31 on the corresponding connecting portions 21.

Specifically, the bonding terminals 41 are disposed corresponding to the bonding area.

Specifically, referring to FIGS. 2 and 3, each of the bonding terminals 41 comprises an end portion 411 and a trace 412, and for each of the bonding terminals 41, a projection of the end portion 411 in a vertical direction is located at a side of the corresponding connecting portion 21 away from a center of the flexible substrate 10, and one end of the trace 412 is connected to the end portion 411, and the other end of the trace is in contact with the corresponding connecting portion 21 through a via hole 31 on the corresponding connecting portion 21.

Specifically, in the embodiment shown in FIGS. 2 and 3, shapes of the plurality of end portions 411 are all rectangular. Certainly, the plurality of connecting portions 21 and the plurality of end portions 411 may have other shapes according to actual product requirements.

Specifically, in the embodiment shown in FIGS. 2 and 3, the plurality of end portions 411 are arranged in a straight line. Furthermore, an arrangement direction of the plurality of connecting portions 21 is parallel to an arrangement direction of the plurality of end portions 411.

Specifically, the manufacturing method further comprises a step of separating the rigid substrate 60 from the flexible substrate 10 after Step S5.

Specifically, in the manufacturing method of the TFT array substrate of the present invention, the plurality of via holes 31 are respectively located on the plurality of connection portions 21 of the first metal layer 20 in the insulating layer 30 on the first metal layer 20, and then, the second metal layer 40 is formed on the insulating layer 30, such that the plurality of bonding terminals 41 of the second metal layer 40 are respectively in contact with the plurality of connecting portions 21 through the via holes 31, thereby the plurality of bonding terminals 41 are electrically connected to the first metal layer 40. Thus, the TFT array substrate is bonded to the chip by using the plurality of bonding terminals 41 to bond the chip and the first metal layer 20, an expansion of the first metal layer 20 caused by thermal expansion of the flexible substrate 10 still will not cause bonding offset of the pin of the chip and the bonding terminals 41, that is, bonding offset of the chip and the TFT array substrate will not occur, thereby improving a chip bonding yield of the flexible liquid crystal display panel.

On the basis of the same inventive idea, the present invention further provides a flexible liquid crystal display panel. The flexible liquid crystal display panel includes the aforesaid TFT array substrate and a chip bonded to the TFT array substrate. The structure of the TFT array substrate will not be repeatedly described herein. The chip includes a plurality of pins that are respectively bonded with a plurality of bonding terminals 41 of the TFT array substrate, thereby bonding the TFT array substrate to the chip.

Specifically, in the TFT array substrate of the flexible display panel according to the present invention, the plurality of via holes 31 are respectively located on the plurality of connection portions 21 of the first metal layer 20 in the insulating layer 30 on the first metal layer 20, and then, the second metal layer 40 is formed on the insulating layer 30, such that the plurality of bonding terminals 41 of the second metal layer 40 are respectively in contact with the plurality of connecting portions 21 through the via holes 31, thereby the plurality of bonding terminals 41 are electrically connected to the first metal layer 40. Thus, the TFT array substrate is bonded to the chip by using the plurality of bonding terminals 41 to bond the chip and the first metal layer 20, an expansion of the first metal layer 20 caused by thermal expansion of the flexible substrate 10 still will not cause bonding offset of the pin of the chip and the bonding terminals 41, that is, bonding offset of the chip and the TFT array substrate will not occur, thereby improving a chip bonding yield of the flexible liquid crystal display panel.

In conclusion, the TFT array substrate includes a flexible substrate, a first metal layer disposed over the flexible substrate, an insulating layer covering the first metal layer and a second metal layer disposed on the insulating layer. The first metal layer includes a plurality of connection portions at intervals. The second metal layer includes a plurality of bonding terminals at intervals. Each bonding terminal corresponds to one connecting portion. The insulating layer is provided with a plurality of via holes respectively on the connecting portions. The plurality of bonding terminals are respectively in contact with the corresponding connecting portions through the via holes on the corresponding connecting portions. After the bonding terminal is connected to the pin of a chip to bond the TFT array substrate and the chip, an expansion of the first metal layer caused by thermal expansion of the flexible substrate does not cause bonding offset of the chip and the TFT array substrate, thereby improving a chip bonding yield of the flexible liquid crystal display panel. The manufacturing method of the TFT array substrate of the present invention can eliminate the bonding offset problem of the TFT array substrate and the chip, and can improve the chip bonding yield of the flexible liquid crystal display panel. The flexible display panel of the present invention can eliminate the bonding offset problem of the TFT array substrate and the chip, and can improve the chip bonding yield of the flexible liquid crystal display panel.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A thin film transistor (TFT) array substrate, comprising: a flexible substrate, a first metal layer disposed over the flexible substrate, an insulating layer covering the first metal layer and a second metal layer disposed on the insulating layer;
wherein the first metal layer comprises a plurality of connection portions at intervals; the second metal layer comprises a plurality of bonding terminals at intervals; each bonding terminal corresponds to one connecting portion; the insulating layer is provided with a plurality of via holes respectively on the connecting portions; the plurality of bonding terminals are respectively in contact with the corresponding connecting portions through the via holes on the corresponding connecting portions.

2. The TFT array substrate according to claim 1, wherein a material of the flexible substrate is Polyethylene terephthalate (PET) or Polyimide (PI).

3. The TFT array substrate according to claim 1, wherein each of the bonding terminals comprises an end portion and a trace, and for each of the bonding terminals, a projection of the end portion in a vertical direction is located at a side of the corresponding connecting portion away from a center of the flexible substrate, and one end of the trace is connected to the end portion, and an other end of the trace is in contact with the corresponding connecting portion through a via hole on the corresponding connecting portion.

4. The TFT array substrate according to claim 3, wherein shapes of the plurality of connecting portions are all rectangular; shapes of the plurality of end portions are all rectangular.

5. The TFT array substrate according to claim 3, wherein the plurality of connecting portions are arranged in a straight line, and the plurality of end portions are arranged in a straight line.

6. The TFT array substrate according to claim 4, wherein an arrangement direction of the plurality of connecting portions is parallel to an arrangement direction of the plurality of end portions.

7. The TFT array substrate according to claim 1, wherein the insulating layer is correspondingly provided with two via holes on each of connecting portions, and the plurality of bonding terminals are respectively in contact with the corresponding connecting portions through the two via holes on the corresponding connecting portions.

8. The TFT array substrate according to claim 1, further comprising a buffer layer disposed on the flexible substrate;
wherein the first metal layer is disposed on the buffer layer.

9. A manufacturing method of a thin film transistor (TFT) array substrate, comprising steps of:
Step S1, providing a flexible substrate;
Step S2, forming a buffer layer on the flexible substrate;
Step S3, depositing a metal material on the buffer layer, and patterning the metal material to form a first metal layer; wherein the first metal layer comprises a plurality of connecting portions at intervals;
Step S4, forming an insulating layer covering the first metal layer, and patterning the insulating layer to form a plurality of via holes respectively disposed on the plurality of connecting portions;
Step S5, depositing a metal material on the insulating layer, and patterning the metal material to form a second metal layer; wherein the second metal layer comprises a plurality of bonding terminals at intervals; each bonding terminal corresponds to one connecting portion; the plurality of bonding terminals are respectively in contact with the corresponding connecting portions through the via holes on the corresponding connecting portions.

10. A flexible liquid crystal display panel, comprising the TFT array substrate according to claim 1.
